(19) United States
(12) Patent Application Publication
(10) Pub. No.: US 2010/0282287 A1
(43) Pub. Date: Nov. 11, 2010

(54) Solar-charge

(75) Inventor: Thomas Paul Corcoran, Farmington, MO (US)

Correspondence Address: Thomas P. Corcoran, 3668 Williams Road, Farmington, MO, 63640, US

(73) Assignee: Thomas Paul Corcoran, Farmington, MO (US)

(21) Appl. No.: 12/220,782

(22) Filed: Jul. 29, 2008

(51) Int. Cl. H01L 31/042

(52) U.S. Cl. 136/244

(57) ABSTRACT

This process of charging electric and electrically backed up vehicles is done through roof mounted solar panels. With the rising cost and burning fossil fuels, it is designed to extend battery duration while in transit, keeping the electric motors running longer. These solar panels adhere directly to the roofs of any trailer in tow, being very thin, they keep the trailer aerodynamic. This technology is to be used in conjunction with the development of trucks using hybrid technology. Also, this process can be used to power the basic electrical needs of the truck the trailer is connected to, including the air conditioning.

### BACKGROUND OF THE INVENTION

The automotive industry continues to adapt to the changing market in the United States and abroad. We hear each day of new innovations that lessen the dependence on foreign oil. With this demand a growing number of electric/electric backup vehicles are being produced. In the larger scheme of things, in just a matter of time, there will be larger trucks that will make use of this technology. This invention is to enhance that projection.

The crux of the process to be patented is the use of solar panels adhered to the roof of “Semi Trailers”, as well as any smaller enclosed van type trailers that could be towed with any smaller truck. At the present time the most likely source for these panels, would be a company named “United Solar Ovonic”, trademark UNI-SOLAR. They produce a very thin flexible solar panel that is designed to adhere to metal roofs of buildings with a high wind resistance.

### BRIEF SUMMARY OF THE INVENTION

This system of producing electricity through a trailer roof mounted solar array, will use as it's model the Ovonic flexible photo voltaic laminate system made by United Solar Ovonic. These flexible solar panels come in lengths of 5.5 m×0.4 m or 2.85 m×0.4 m, with a nominal power of 136 Wp and 68 Wp respectively. They will be adhered permanently in arrays to the roof of: closed van semi trailers, straight truck van type, smaller closed in trailers pulled as fifth wheels, or virtually any trailer to be pulled that has roof space to arrange an array of solar panels on it.

### DETAILED DESCRIPTION OF THE INVENTION

The patent sought here is for the “PROCESS” of using photo voltaic solar panel arrays, mounted on the roofs of trailers, pulled by vehicles using electric and battery power. The process will be set up in accordance with the needed output to the vehicles system. hooked up in series, these solar panels can be adapted to a wide variety of voltage/amperes output.

A typical semi trailer would be 53′ at the present time, this would allow for an array of 15−5.5 m×0.4 m and 5−2.85×0.4 laminate solar panels, to form a combined output of 2,380 Wp. The array would be configured to the proper voltage/amperes conducive to the vehicle charging system it is being supplied to. The wiring that connects it to the pulling vehicle will be wired along with the trailers other standard systems and connected through a cable system in a similar way.

As technology develops; stronger, higher capacity and greater output can be used in the same process. At the present time United Solar Ovonic has the lead on the technology, these flexible panels with coil stainless steel backing, actually put out more power than most standard panels.

For the present, the system will be used as an alternative charging system for over the road trucks. This system will enable it's use during daylight hours to keep the generating system on the truck from kicking in. Thereby saving the added horsepower needed to run those generators. This will save fuel, especially since there are so many add on features in the modern trucks.

1. This system will supplement electric charging systems of any towing vehicle that pulls any closed van type trailer.

2. This system has the potential to save fossil fuel used by vehicles towing trailers, with the vehicles having electric or battery supplemental power.

3. This process will add to the hybrid systems that are now being developed and will help motivate development of trucks using alternative supplemental electric or battery power.

4. This process can be used on any sized trailer, even ones that can be pulled behind vehicles like the “Chevy Tahoe” that currently uses a hybrid system, providing additional electric charge to batteries.

5. Semi Tractor Trailers can be developed using supplemental electric/battery power to save on the rising cost of fuel. This system will provide a viable addition to the charging system.

6. This process can be used to deliver virtually all electrical power needed for the operation of over the road “Semi” trucks. Keeping the initial generator based charging system from kicking in. Thereby allowing decreased carbon emissions by reducing the added horsepower needed to turn the generator and reducing fuel consumption.

7. This system can be used to also provide power to the trailer portion of these “Semi-Trucks” like commercial refrigeration units that keep cargo cold between destinations. This would include travel trailers or any type of trailer that would need electrical power to run air, etc.
